(19) United States
(12) Patent Application Publication
(10) Pub. No.: US 2012/0261689 A1
(43) Pub. Date: Oct. 18, 2012

(54) SEMICONDUCTOR DEVICE PACKAGES AND RELATED METHODS

(76) Inventors: Bernd Karl Appelt, Gulf Breeze, FL (US); Richard Alan Rice, Morgan Hill, CA (US); Andrew T.W. Lee, Milpitas, CA (US)

(21) Appl. No.: 13/086,280

(22) Filed: Apr. 13, 2011

(51) Int. Cl. H01L 33/62; H01L 33/52

(52) U.S. Cl. 257/98; 438/27; 257/E33.059

(57) ABSTRACT

The packages include a plurality of spaced conductive standoffs electrically coupling the semiconductor die to, variously, a substrate and bottom package contacts. The conductive standoffs may be pillars or posts. The substrate includes at least one electrically isolated portion, which has exposed sidewalls.

### TECHNICAL FIELD

The present disclosure relates to semiconductors and more particularly to semiconductor assembly and packaging.

### BACKGROUND

A light-emitting diode (LED) is a semiconductor light source fashioned on a die, which is a small block of semiconducting material. LEDs are used as indicator lamps in many devices, and are increasingly used for lighting as the brightness and light emitting efficiency of LED dies have advanced. The lifespan of LED light sources is orders of magnitude greater than that of incandescent light sources. However, LED light sources can present challenges related to heat dissipation. When an LED die operates at high temperatures, the light emission and color veracity of the LED die can degrade.

To achieve proper heat dissipation, high brightness and high power, LEDs have migrated to ceramic substrate-based packaging. However, ceramic substrates are notoriously expensive. Thus, the industry is searching for more cost-effective packaging configurations with good heat dissipation efficiency.

### SUMMARY

One of the present embodiments comprises a semiconductor package. The package comprises a leadframe including an isolated block and at least one lead at a periphery of the package. The isolated block has a lateral surface. The lateral surface has a sloped upper portion and a sloped lower portion. A junction of the sloped upper portion and the sloped lower portion defines an apex. The at least one lead has a lateral surface. The lateral surface has a sloped upper portion and a sloped lower portion. A junction of the sloped upper portion and the sloped lower portion defines an apex. The package further comprises a plurality of conductive standoffs coupled to an upper surface of the isolated block and the at least one lead. The package further comprises a die coupled to the plurality of conductive standoffs with a space between the die and the isolated block. The package further comprises a package body at least partially encapsulating the die, the sloped upper portions of the isolated block, and the at least one lead. The sloped lower portions of the isolated block and the at least one lead protrude from the package body.

Another of the present embodiments comprises a semiconductor package. The package comprises a leadframe including an isolated block and at least one lead at a periphery of the package. The isolated block has a lateral surface. The lateral surface has a sloped upper portion and a sloped lower portion. A junction of the sloped upper portion and the sloped lower portion defines an apex. The at least one lead has a lateral surface. The lateral surface has a sloped upper portion and a sloped lower portion. A junction of the sloped upper portion and the sloped lower portion defines an apex. The package further comprises a die coupled to the isolated block and electrically connected to the at least one lead. The package further comprises a first encapsulant encapsulating a portion of the die, the sloped upper surfaces of the isolated block, and the at least one lead. The sloped lower portions of the isolated block and the at least one lead protrude from the first encapsulant. The package further comprises a second encapsulant encapsulating a light emitting portion of the die. The second encapsulant permits the passage of light.

Another of the present embodiments comprises a method of making a semiconductor package. The method comprises forming conductive layers on top and bottom surfaces of a substrate. The method further comprises forming an opening in the substrate to thereby define an isolated block and a plurality of leads at a periphery of the package. The isolated block has a lateral surface. The lateral surface has a sloped upper portion and a sloped lower portion. A junction of the sloped upper portion and the sloped lower portion defines an apex. The at least one lead has a lateral surface. The lateral surface has a sloped upper portion and a sloped lower portion. A junction of the sloped upper portion and the sloped lower portion defines an apex. The method further comprises forming a plurality of conductive standoffs on an upper surface of the isolated block and the leads. The method further comprises coupling a die to the plurality of conductive standoffs with a space between the die and the isolated block. The method further comprises forming a package body coupled to the package such that the body at least partially encapsulates the die, the sloped upper portions of the isolated block, and the sloped upper portions of the leads. The sloped lower portions of the isolated block and the leads protrude from the package body.

Another of the present embodiments comprises a semiconductor package. The package comprises a substrate having a conductive top layer, a conductive bottom layer, and a dielectric layer between the top and bottom layers. A plurality of conductive elements are formed on the top layer. A die is coupled to the conductive elements and spaced from the top layer. An underfill occupies spaces between adjacent ones of the conductive elements. The package further comprises a package body at least partially encapsulating the die.

### BRIEF DESCRIPTION OF THE DRAWINGS

FIGS. 1A-1H are schematic cross-sectional and top plan views of various steps in a semiconductor packaging process according to one of the present embodiments, wherein FIGS. 1B′ and 1C′ are top plan views;

FIG. 2 is a schematic cross-sectional view of a semiconductor package structure according to one of the present embodiments;

FIGS. 3A-3E are schematic cross-sectional views of various steps in a semiconductor packaging process according to another of the present embodiments;

FIGS. 4A-4G are schematic cross-sectional and top plan views of various steps in a semiconductor packaging process according to another of the present embodiments, wherein FIG. 4A′ is a top plan view;

FIG. 5 is a schematic cross-sectional view of a semiconductor package structure according to another of the present embodiments;

FIG. 6 is a schematic cross-sectional view of a semiconductor package structure according to another of the present embodiments;

FIGS. 7A-7I are schematic cross-sectional and top plan views of various steps in a semiconductor packaging process according to another of the present embodiments, wherein FIG. 7D′ is a top plan view;

FIGS. 8A and 8B are schematic cross-sectional views of semiconductor package structures according to others of the present embodiments; and

FIGS. 9A-9H are schematic cross-sectional views of various steps in a semiconductor packaging process according to another of the present embodiments.

Common reference numerals are used throughout the drawings and the detailed description to indicate the same elements. The present invention will be more apparent from the following detailed description taken in conjunction with the accompanying drawings.

### DETAILED DESCRIPTION

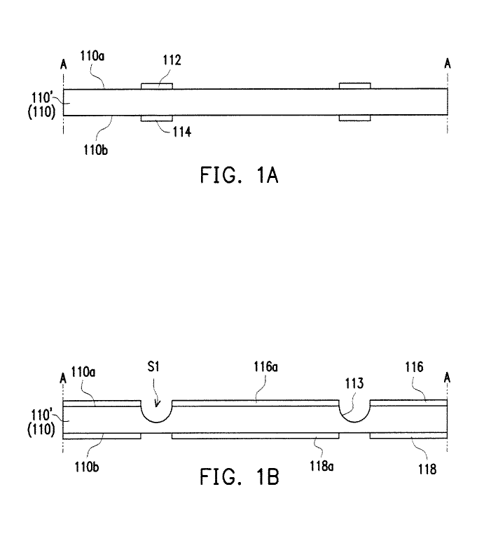

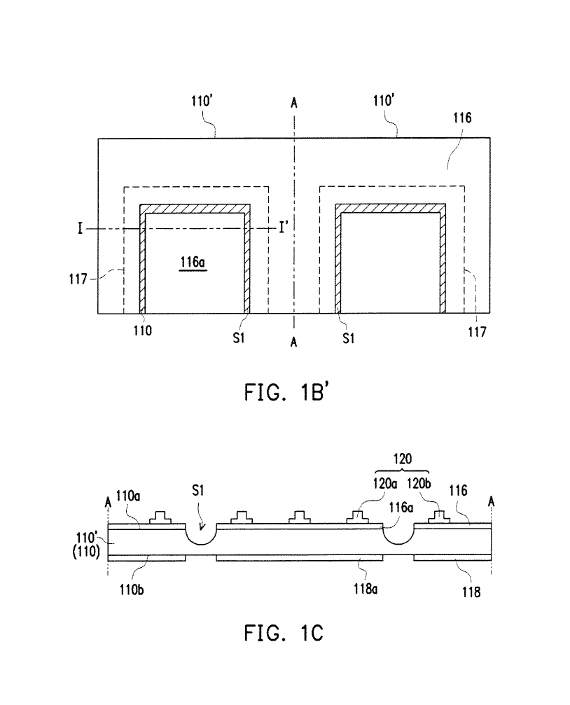

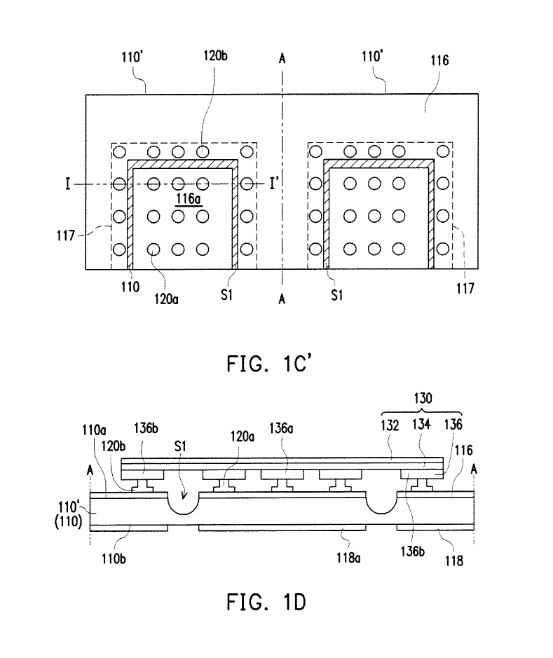

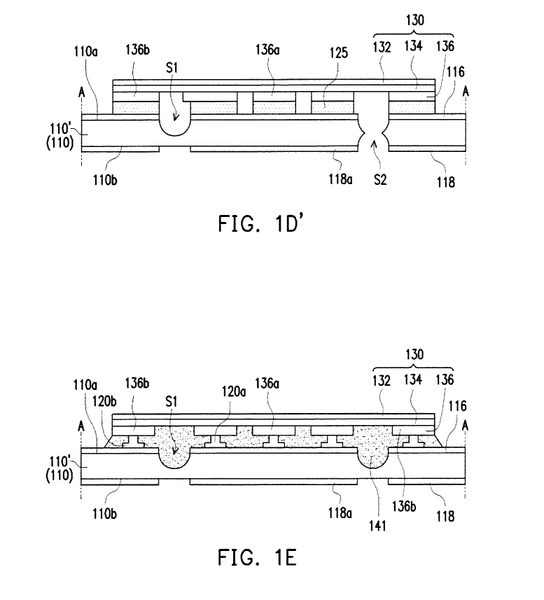

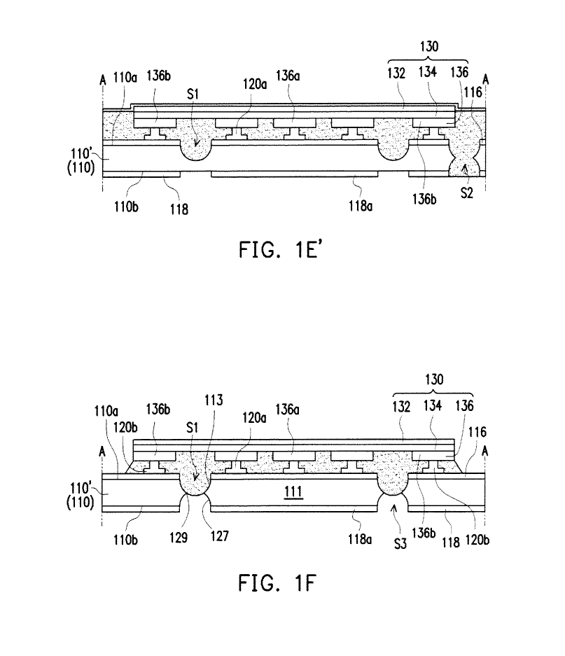

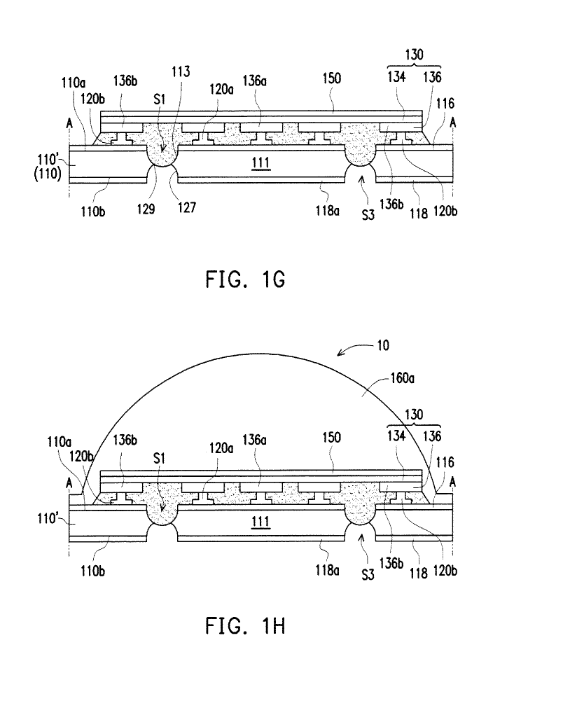

In FIGS. 1A-1H, one embodiment of a process for making leadframe semiconductor package structures is illustrated. Referring to FIG. 1A, the process begins with a substrate 110 having an upper surface 110a and a lower surface 110b. The illustrated substrate 110 includes a plurality of substrate units 110′, which are indicated by break lines A-A. In some embodiments a plurality of attached substrate units 110′ are fabricated simultaneously, or in sequence, and later separated from one another along the break lines A-A. For simplicity, the terms substrate 110 and substrate unit 110′ may be used interchangeably herein.

The substrate 110 can be, for example, a metal such as copper, a copper alloy, or any other material having good electrical and thermal conductivity. A first photoresist layer 112 and a second photoresist layer 114 are formed on the upper surface 110a and lower surface 110b, respectively, of the substrate 110. In certain embodiments, the first and second photoresist layers 112, 114 may be formed by laminating a dry film resist (DFR) layer (not shown) on the upper surface 110a of the substrate 110, exposing the DFR layer to light, and then developing the DFR layer to form patterns in the DFR layer. Alternatively, a photoresist layer may be provided with preformed patterns.

Referring to the FIG. 1B, using the first and second photoresist layers 112, 114 as a mask, a first conductive layer 116 and a second conductive layer 118 are formed on the upper surface 110a and lower surface 110b, respectively, of the substrate 110. Then, the first and second photoresist layers 112, 114 are removed. The first and second conductive layers 116, 118 may be metal, or any other material, and may be formed by plating, electroplating, foil lamination, or by any other process. Either or both of the first and second conductive layers 116, 118 may be a stacked nickel/gold layer, for example.

The first conductive layer 116 includes a plurality of first metal blocks 116a, while the second conductive layer 118 includes a plurality of second metal blocks 118a. In general, the pattern of the second conductive layer 118 corresponds to that of the first conductive layer 116 in FIG. 1B. However, in other embodiments the pattern of the second conductive layer 118 may be different from the pattern of the first conductive layer 116 in order to meet desired product characteristics.

With further reference to FIG. 1B, using the first conductive layer 116 as an etching mask, a first etching process is performed to remove upper portions of the substrate 110 and form a plurality of upper trenches S1 in the upper surface of the substrate 110. Each of the upper trenches S1 includes sloped upper surfaces 113. The first etching process is a half-etch process, since only upper portions of the substrate 110 are removed. The first etching process may be an isotropic etching process, for example.

FIG. 1B′ provides a top plan view of the substrate 110. Note that FIG. 1B′ shows a different portion of the substrate 110 than FIG. 1B. Whereas FIG. 1B shows a portion of a single substrate unit 110 taken along the cut line I-I′, FIG. 1W shows portions of two side-by-side substrate units 110′, with each substrate unit 110′ defined by the break line A. As shown, the shape of each first metal block 116a is rectangular, but may be any shape, such as round. Each block 116a may be further divided into multiple blocks by additional upper trenches S1 (not shown) formed in the first etching process. As further described below, each of the first metal blocks 116a receives at least one die. The upper trenches S1 surrounding the first metal blocks 116a create additional surface area for convective heat transfer, enabling the first metal blocks 116a, the underlying portions of the substrate 110, and the second metal blocks 118a to function as a heat sink for the die.

With continued reference to FIG. 1B′, each upper trench S1 rings, or encloses, the central metal block 116a of the first conductive layer 116. The upper trenches S1 are located within die shadow locations 117, i.e. the die mounting region. In the illustrated embodiment, the upper trench S1 is smaller in plan area than the die shadow 117. However, in alternative embodiments the upper trench S1 may be larger in plan area than the die shadow 117. Further, as shown in FIG. 1B′ each substrate unit 110′ includes only one upper trench S1. In alternative embodiments multiple openings could be provided on each substrate unit 110′ to meet thermal design requirements. Optionally, an anti-tarnish layer may be formed over the metal film 110 in the area outside the die mounting region, thereby acting as a reflective surface to increase the luminosity of the light emitted from an LED die. The optional anti-tarnish layer may be a nickel layer or a silver layer, for example and without limitation.

The package substrate 110 may include a plurality of package substrate units 110′ arranged in strips or arrays. While square and rectangular substrates are most efficient for material utilization, the substrate may be any shape, including irregular shapes, to suit product design needs.

FIGS. 1C and 1C′ illustrate a subsequent step in the present process, in which a plurality of conductive elements 120 is formed on the first conductive layer 116. The conductive elements 120 include central conductive elements 120a located on the first central metal block 116a, and peripheral conductive elements 120b located outside the upper trench S1. The conductive elements 120 provide spacing between the die 130 and the substrate 110, and thus may also be referred to as standoffs. As discussed in detail below, the conductive elements 120 within the package can greatly improve the efficiency of heat dissipation.

In the illustrated embodiment, the conductive elements 120 are pillars having an inverted T-shaped profile. Pillars are advantageous because they avoid wire bond connections and are compatible with a die 130 having electrodes on its lower surface. With an LED die 130 oriented as shown in FIG. 1D, discussed below, a light-emitting portion of the die 130 faces upward, thereby maximizing luminosity. However, in alternative embodiments the conductive elements 120 can be pillars having different profile shapes, such as a non-inverted T, straight pillars, bumps, or any other type of conductive element. The conductive elements 120 may be formed by wire bonding, high-speed jetting, plating, or any other process. In the case of T-shaped pillars, the plating process may comprise two steps. The conductive elements 120 may have any composition, such as gold and its alloys, silver and its alloys, copper, conductive polymers, or any other material having good electrical and thermal conductivity If the conductive elements 120 are pillars, they may be copper and have an optional nickel/gold top layer, which optional layer may be formed by pattern plating. Alternatively, the conductive elements 120 could be pillars having a copper core with solder on either end for attaching to the first conductive layer 116 and the die 130. Alternatively, the conductive elements 120 could be bumps formed by wire bonding and connected to the first conductive layer 116 through thermo-sonic bonding. The conductive elements 120 could be solder bumps, but solder bumps formed on metal may have a shorter lifespan due to intermetallic compounds (IMC) growth. Gold conductive elements directly bonded to the conductive layer 116 provide longer lifespan without the formation of IMC.

The locations of the conductive elements 120 correspond to locations of electrodes on the die, which is mounted in a subsequent step. With reference to FIG. 1C′, the locations of the conductive elements 120 are within the die shadow 117. However, the number and locations of the conductive elements 120 can be varied to suit product design needs, such as thermal requirements.

Although the conductive elements 120 in FIG. 1C/1C′ are formed on the leadframe structure, the conductive elements 120 could be provided on the dies before mounting them to the leadframe structure. Taking copper pillars as an example, it may be preferable to provide such pillars on the dies before mounting, as better pillar planarity might be achieved.

FIG. 1D illustrates a subsequent step in the present process, in which a die 130 is mounted on each substrate unit 110′. The die 130 sits atop the conductive elements 120. The die 130 may be connected to the conductive elements 120 through thermo-sonic bonding, or any other process. Further, in certain embodiments, the die 130 may be a light-emitting diode (LED) die. Only one die 130 is shown in FIG. 1D, but several dies 130 may be mounted on a single substrate unit 110′. For example, in the case of an LED die, more than one die may be needed to achieve desired light intensity and/or color.

The die 130 includes a substrate 132, a semiconductor layer 134 on the substrate 132, and a plurality of pads 136 on the semiconductor layer 134. The substrate 132 may be sapphire, or any other material, and may also be referred to as an illuminating layer. Further, in certain embodiments, the pads 136 may be metal, or any other material. The die 130 may include other layers (not shown).

The die 130 is electrically connected to the substrate 110 through the conductive elements 120 and the pads 136. The pads 136 may function as cathodes, anodes or ground electrodes. For example, if the die 130 is an LED power chip, a central electrode 136a, which is surrounded by the upper trench S1, may be an anode, while the peripheral electrodes 136b, which are outside the upper trench S1, may be cathodes, or vice versa.

In the illustrated embodiment, the locations of the conductive elements 120 correspond to the locations of the pads 136 of the die 130 in a one-to-one fashion. The central pads 136a are coupled to the central conductive elements 120a, while the peripheral pads 136b are coupled to the peripheral conductive elements 120b. The central pads 136a thus serve as a first electrode and the peripheral pads 136b serve as a second electrode. In alternative embodiments, there may be more than one conductive element 120 per pad 136 to enhance thermal and electrical conductivity. Adding additional conductive elements 120 advantageously increases heat transfer from the die. In fact, some conductive elements 120 may function strictly for heat transfer. As many conductive elements 120 may be provided per pad 136 as space allows.

In all embodiments herein, only one die 130 is shown mounted on each substrate unit 110′. However, more than one die 130 may be arranged on each substrate unit 110′. For example, a plurality of LED dies of different colors may be combined on a substrate unit 110′ to achieve desired color and/or lighting schemes. Further, and again in all embodiments herein, one or more protective devices (not shown), such as Zener diodes, may be provided anywhere in the electrical circuit that includes the die 130 in order to protect the die 130 from overheating.

With reference to FIG. 1D′, the substrate 110 may include at least one vent opening S2. The vent openings S2 facilitate out-gassing during mold injection. Under certain circumstances, a thermally enhanced mold compound layer 125 may be provided between the die 130 and the first conductive layer 116 to achieve non-electrical connections. The mold compound may be injected through the openings S2, and may also fill the trench S1.

FIG. 1E illustrates a subsequent step in the present process, in which an underfill 140 is formed between the die 130 and the first conductive layer 116. The underfill 140 may advantageously increase adhesion between the die 130 and the substrate 110, and also reinforce the strength of the finished package. The underfill 140 may also be highly thermally conductive to enhance heat transfer between the die 130 and the leadframe structure. For example, the underfill 140 may contain thermally conductive particles to enhance its conductive properties. In the illustrated embodiment, the underfill 140 completely fills the upper trenches S1 and abuts the upper sloped surfaces 113, but in alternative embodiments it may not. The underfill 140 may be formed by a capillary underfill process, for example. The composition of the underfill 140 may be, for example and without limitation, epoxy-based resin filled with thermally conductive particles 141 like alumina, aluminum nitride, or boron nitride.

With reference to FIG. 1E′, the underfill 140′ may alternatively be formed by a flushed-under molding process, or a molded underfill process. Using a protective film 115 attached to the inner surface of a transfer mold (not shown) in a film assisted molding process over the dies 130, the underfill material flushes over the substrate 110 and fills spaces between the dies 130 and between the protective film and the first conductive layer 116. The protective film 115 may be, for example, a compliant film in the form of a continuously fed tape. The transfer mold would then be placed over a portion of the film tape during the underfill process. The substrate 132 is not exposed to the underfill 140′, which facilitates subsequent removal of the substrate 132. In general, the underfill 140 or 140′ may be considered as one type of encapsulant in the finished package.

FIG. 1F illustrates a subsequent step in the present process, in which the second conductive layer 118 is used as an etching mask for a second etching process. In the second etching process the substrate 110 is etched on its lower surface 110b to form a plurality of lower trenches S3. Each of the lower trenches S3 includes sloped lower surfaces 127. Further, the lower surfaces 127 adjoin the upper surfaces 113 of the upper trenches S1 at a peak 129.

The lower trenches S3 expose the underfill 140 in the upper trenches S1. Through the second etching process and the formation of the lower trenches S3, a plurality of central blocks 111 are electrically isolated from the substrate 110 by the openings formed from the combination of the upper and lower trenches S1, S3. Further, the central conductive elements 120a surrounded by the upper trench S1 are electrically isolated from the peripheral conductive elements 120b outside the upper trench S1. The second etching process is a half-etch process, since only lower portions of the substrate 110 are removed. The second etching process may be an isotropic etching process, for example. It should be appreciated that the isolated blocks 111 need not be located in the center of the package, but could be located anywhere.

FIG. 1G illustrates a subsequent step in the present process, in which the substrate 132 of the die 130 is removed and a phosphor layer 150 is formed on the semiconductor layer 134. The substrate 132 may be removed by laser delamination, for example, or by any other process. The substrate 132 may be removed and the semiconductor layer 134 may be etched or roughened for better emitting efficiency. In alternative embodiments, and as discussed further below, the substrate 132 may be retained to suit product design needs. If the removal of the substrate 132 is not desirable, the shape of the protective film 115 can be adjusted to make the top surfaces of the underfill 140′ and the substrate 132 coplanar.

FIG. 1H illustrates a subsequent step in the present process, in which a package body 160 is formed over the substrate 110 to encapsulate the die 130, the conductive elements 120 and the underfill 140. The package body 160 may be formed with a lens portion 160a. The package body 160 may be made of a transparent molding material, such as epoxy or silicone resin, with optional inorganic fillers to increase reflectivity. A silicon based molding material may be preferred for its resistance to yellowing, while the epoxy based molding material is harder and provides better adhesion. In addition, the package body 160 may further include conversion substance particles, such as phosphor particles, if the phosphor layer 150 is omitted.

In the process described thus far, the underfill 140 and the package body 160 are formed in separate processes, and may comprise different material compositions. However, in alternative embodiments the underfill 140 and the package body 160 may be formed in the same process, and may comprise the same material composition. Further, in other alternative embodiments the package may include no underfill.

In a subsequent step in the present process, the completed packages 10 illustrated in FIG. 1H are separated along the break lines A (FIG. 1G). For example, a singulation process may be performed to separate the substrate units 110′ from one another.

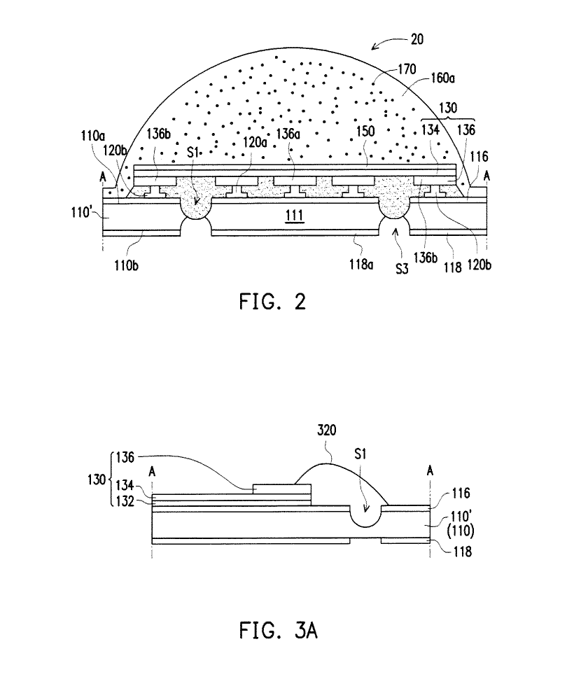

FIG. 2 shows a schematic cross-sectional view of one embodiment of a package structure 20 made according to the foregoing manufacturing steps, except that the substrate 132 is retained and conversion substance particles 170, such as a phosphor, are added. The conversion substance particles 170 luminesce under certain conditions, providing a desired lighting appearance.

In the present embodiments, preferred materials for the underfill 140 and/or the package body 160 have a coefficient of thermal expansion (CTE) between that of the die 130 and the leadframe. Such a CTE reduces stresses between the die 130 and the leadframe. Such materials also put any wire bonds under compression, which reinforces the bonds by reducing shear stresses on the bonds.

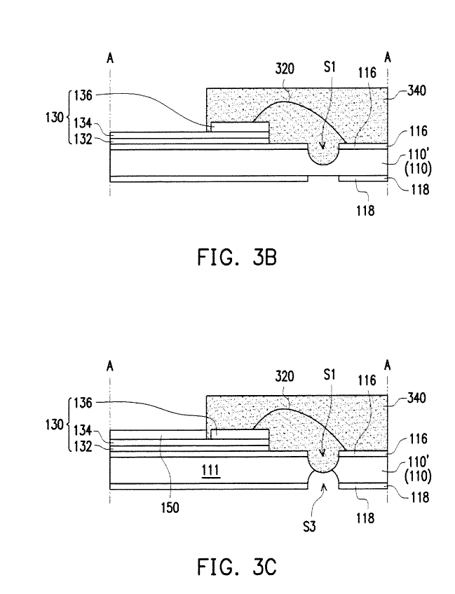

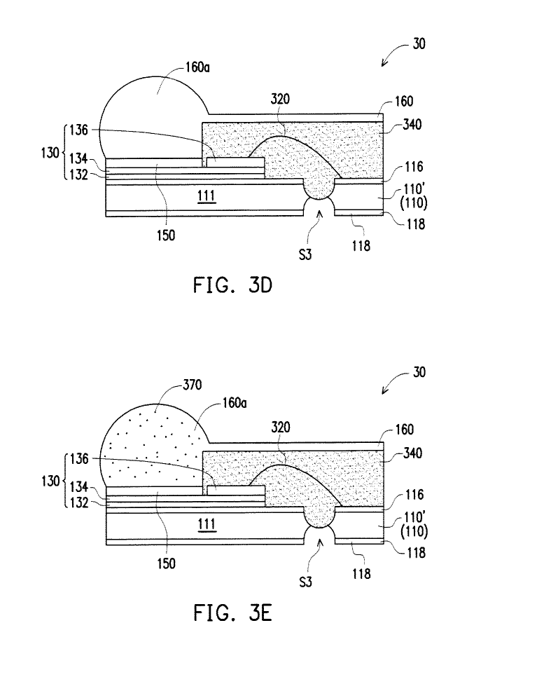

In FIGS. 3A-3E, another embodiment of a process for making leadframe semiconductor package structures is illustrated. Referring to FIG. 3A, the process begins by forming upper trenches S1 in a package substrate 110. This step is similar to that described above with respect to the previous embodiments, except for the location of the trench S1. The upper trenches S1 can be formed according to the steps described above and shown in FIGS. 1A and 1B. A plurality of dies 130 is coupled electrically to the substrate 110. For example, the coupling can be provided by either direct metal bonding or by an electrically conductive adhesive (not shown). In the latter case, the adhesive can be thermally conductive only. A plurality of wires 320 extend between the dies 130 and the first conductive layer 116 of the substrate 110. Only one die is shown in FIG. 3A but several LED dies may be mounted on a single substrate to achieve the desired light intensity and/or color. The die 130 may be an LED chip including a substrate 132 (e.g. a sapphire layer), a semiconductor layer 134 (e.g. a light emitting layer) on the substrate 132 and at least two metal pads 136 on the semiconductor layer 134. The die 130 is electrically connected to the substrate 110 through the wires 320 and the pads 136. Alternatively, a back side metal of the die may also be exposed and connected via wire bonding to the metal pad 116′.

FIG. 3B illustrates a subsequent step in the present process, in which an encapsulant 340 is formed to encapsulate the wires 320 and a portion of the dies 130, and cover a portion of the substrate 110. The encapsulant 340 may be a non-transparent or transparent molding compound, for example. FIG. 3C illustrates a subsequent step in the present process, in which the second conductive layer 118 is used as an etching mask for a second etching process. In the second etching process the substrate 110 is etched from its lower surface 110b to form a plurality of lower trenches S3. The lower trench S3 exposes the encapsulant 340 located in the upper trench S1. Through the second etching process and the formation of the lower trenches S3, a plurality of substrate blocks 111 are isolated from the substrate 110. The second etching process may be, for example, an isotropic etching process. In a previous, concurrent, or subsequent step, a phosphor layer 150 is formed on the semiconductor layer 134 that is not covered by the encapsulant 340.

FIG. 3D illustrates a subsequent step in the present process, in which a package body 160 is formed over the substrate 110 to encapsulate the die 130, the encapsulant 340 and the wires 320. The package body 160 may be formed with a lens portion 160a above a light emitting surface of the die 130. The package body 160 may be made of a transparent molding material, such as epoxy or silicone resin with optional inorganic fillers to increase its reflectivity. The inorganic fillers may be titanium dioxide (TiO₂), for example. The package body 160 may optionally include conversion substance particles 370, such as a phosphor, as shown in FIG. 3E. In a subsequent step in the present process, the completed packages 30 illustrated in FIG. 3D are separated along the break lines A (FIG. 3C). For example, a singulation process may be performed to separate the substrate units 110′ from one another.

The lens portion 160a of the package body 160 may have any shape as required by optical design considerations. In some embodiments, the package body 160 may be formed adjacent to a side surface of the encapsulant 340, but not covering a top surface of the encapsulant 340. Alternatively, it may be desirable to form a package body in one molding operation rather than forming the package body 160 and the encapsulant 340 in two steps.

The processes for assembling semiconductor device packages described above have several advantages. For example, the dies 130 can be mounted to the substrate 110, which includes a plurality of leadframe strips or substrate units 110′. The substrate 110 is singulated after all packages have been assembled. Compared with the conventional process for ceramic based substrates, the leadframe package can be assembled with the leadframe substrate in much larger sizes and is thus more economical.

Further, the present semiconductor device packages also provide several advantages. For example, the conductive elements 120 provide a standoff between the die 130 and the substrate unit 110′. The standoff advantageously enables thermally conductive underfill material 140 to occupy the spaces between the conductive elements 120, thereby providing greater thermal performance and better reliability. Further, the conductive elements 120 may be pillars. Pillars provide greater rigidity as compared to flip chip solder balls. The package 10 is thus able to withstand greater forces, enabling the package 10 to pass more stringent failure tests, such as drop tests and thermal cycling tests. Pillars also can replace wire bonds and provide a better thermal path, which in turn provides thermal performance and increased lifespan. Pillars also advantageously reduce the dark area around the die, which would otherwise comprise mold and/or wire bond area. Pillars thus may enhance luminosity. Further, the die 130 sits on the isolated block 111, which is isolated from the substrate 110 by the opening formed from the combination of the upper and lower trenches S1, S3. The trenches S1. S3 expose sidewalls of the isolated block 111 and of the substrate 110 opposite the isolated block 111, thereby exposing a greater portion of the isolated block 111 and creating greater surface area for more effective convective heat transfer. Further, the present leadframe structure can be fabricated with routable metal patterns (not shown), which improves design flexibility depending on product requirements. For example, a routable metal pattern could connect an LED die to a Zener diode or another die like controller, such as an RF die, a sensor, etc., for self-contained LED systems. Further, these additional components may be thermally isolated from the die, so that heating of one component will not influence heating of the other.

In the present embodiments, materials chosen for the underfill and mold compound(s) may be chosen to be highly thermally conductive when under the LED die. For other components, standard underfill and mold compounds may be chosen. Due to the separation of components by trenches, heat transfer happens primarily through thermal conduction through wiring traces on the substrate 110, while dielectic materials like the package body 160, the underfill 140, and dielectric materials on the substrate 110 provide significantly less heat transfer. This configuration creates a strong temperature gradient, effectively keeping other components on the substrate 110, such as a controller and/or a sensor, significantly cooler than the die 130.

The main thermal path from the die 130 is through the conductive elements 120 and underfill 140 to the substrate 110, and from there to a motherboard (not shown) to which the package is attached, and from there to an attached heat sink (not shown). Another thermal path from the die 130 is through the package body 160. Heat is then transferred from the surface of the package body 160 through convection into the surrounding medium. In the case of wirebonded dies, such as in FIG. 3E, another thermal path from the die 130 is through the bond wire 320 to the substrate 110, and from there to a motherboard (not shown) to which the package is attached, and from there to an attached heat sink (not shown).

The encapsulant 340 serves to protect the bond wire 320 and its bonds to the substrate 110 and the die 130. As mentioned above, the package body 160 may be made of a transparent molding material, such as epoxy or silicone resin. By contrast, the encapsulant 340 may be a more conventional mold material, such as an epoxy based mold compound. If the package body 160 is also epoxy, good adhesion can be achieved between the package body 160 and the encapsulant 340. If the package body 160 is silicone, some treatment may need to be applied at the interface between the package body 160 and the encapsulant 340 to achieve good adhesion.

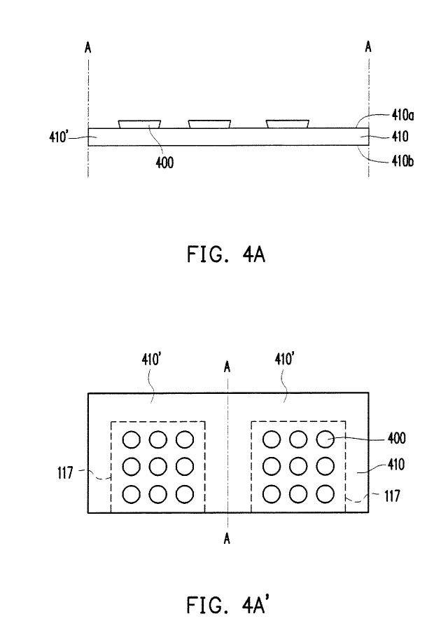

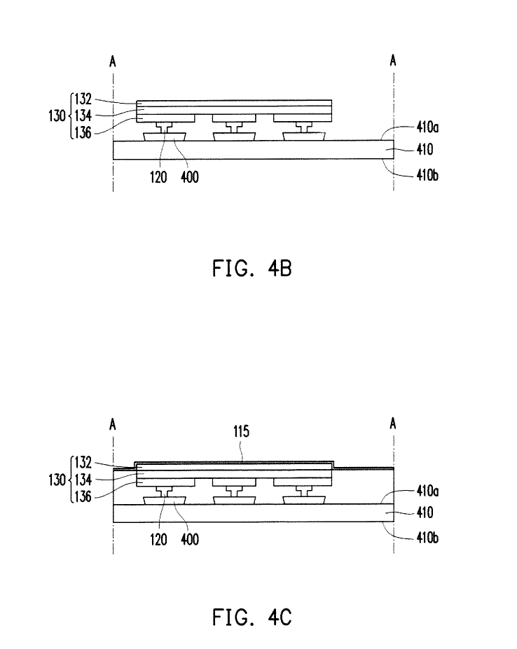

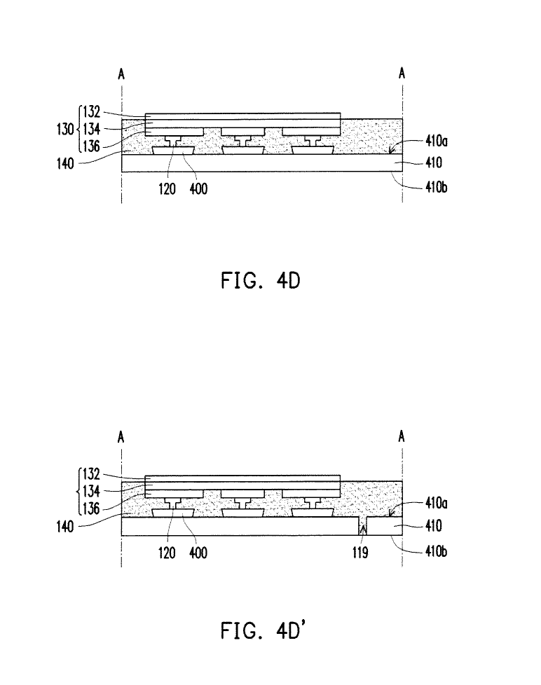

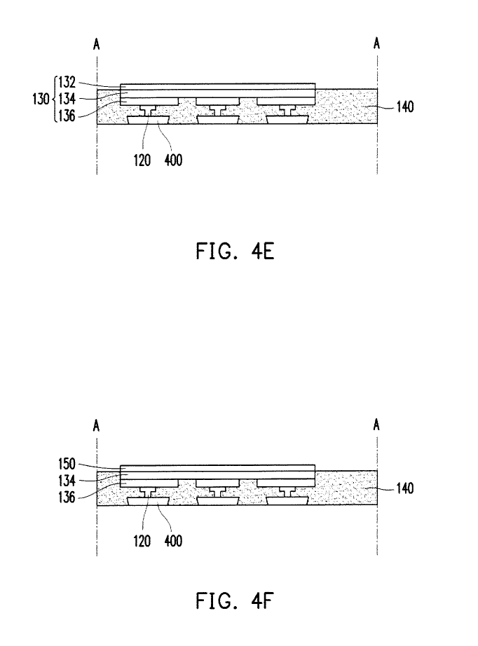

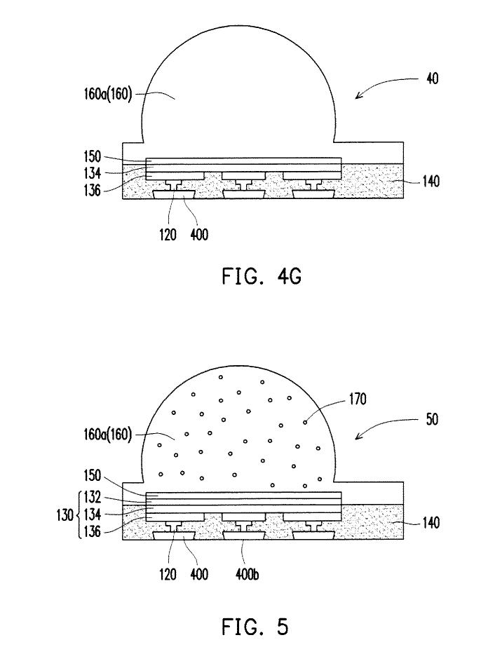

In FIGS. 4A-4G, another embodiment of a process for making leadframe semiconductor package structures is illustrated. Referring to FIG. 4A, the process begins with a carrier 410 having an upper surface 410a and a lower surface 410b. The upper surface 410a may include a release coating (not shown) to facilitate release of the carrier 410 from any adjoining components in a later process step. While square and rectangular leadframe packages are most efficient for material utilization, the leadframe may be any shape, including irregular shapes, to suit product design needs. The carrier 410 may be made from stainless steel or any other material.

The carrier 410 may, for example, function as a transient carrier for at least one package unit 40 (FIG. 4G), with the package units 40 arranged in strips or arrays. The illustrated carrier 410 includes a plurality of carrier units 410′, which are indicated by break lines A-A. In some embodiments a plurality of attached substrate units 110′ are fabricated simultaneously, or in sequence, and later separated from one another along the break lines A-A. For simplicity, the terms carrier 410 and carrier unit 410′ may be used interchangeably herein.

A plurality of conductive lands 400 are formed on the upper surface 410a of the carrier 410. In one embodiment, the conductive lands 400 may be formed by screen-printing silver paste over the carrier 410, and then sintering to form the lands 400. Alternatively, the conductive lands 400 may be made of other metal materials, such as gold, a nickel/gold alloy, copper, any other metal, or combinations thereof. The lands 400 may also be formed by pattern plating. In another embodiment, the conductive lands 400 may be a stacked copper/nickel/gold pad structure. In certain non-limiting embodiments, a height of each land 400 may range from about 5 microns to about 50 microns, for example. The lands 400 may be provided in arrays, or in other arrangements.

FIG. 4A′ provides a top plan view of the carrier 410. Note that FIG. 4A′ shows a different portion of the carrier 410 than FIG. 4A. Whereas FIG. 4A shows a portion of a single substrate unit 110′ taken along the cut line I-I′, FIG. 4A′ shows portions of two side-by-side substrate units 110′, with each substrate unit 110′ defined by the break line A. As shown in FIG. 4A′, the locations of the conductive lands 400 are distributed within a die shadow 117. The carrier 410 with the conductive lands 400 can be considered a leadframe structure. As shown in the top plan view of FIG. 4A′, the shape of each conductive land 400 is round, but may be any shape, such as square, for example, or even an irregular shape.

FIG. 4B illustrates a subsequent step in the present process, in which a plurality of dies 130 are coupled to the conductive lands 400 via a plurality of conductive elements 120. The conductive elements 120 may be formed on the lands 400 prior to placement of the dies 130. Alternatively, the conductive elements 120 may be formed on the dies 130 before the dies 130 are coupled to the leadframe structure. Taking copper pillars as an example, it may be preferable to provide the pillars on the dies 130 before mounting, as better pillar planarity may be achieved. The structures of and methods for forming the conductive elements 120 and the dies 130 are similar to those described above, and will not be repeated here. However, whereas the conductive elements 120 shown in FIGS. 1C-1H and 2 are shaped as an inverted T, the conductive elements 120 shown in FIGS. 4B-4G and 5 are shaped as a rightly oriented T. Differences in the orientation of the T-shaped pillars may result from the conductive elements being formed first on the substrate 110/carrier 410 in a first variation of the process, and first on the die 130 in a second variation of the process.

The locations of the conductive elements 120 correspond to locations of electrodes (not shown) on the die 130. The die 130 is electrically and thermally connected to the conductive lands 400 through the conductive elements 120 and the pads 136. The lands 400 thus may function as a heat sink after the carrier 410 is released. The size of each land 400 can be tailored according to the printing resolution for better heat spreading. The conductive elements 120 within the package improve the efficiency of heat dissipation, because they have good thermal conductivity and they provide a short path between the die 130 and the conductive lands 400. In the illustrated embodiment, one conductive element 120 is provided on each conductive land 400. However, the number and locations of the conductive elements 120 can be modified based on product designs and thermal requirements. For example, more than one conductive element 120 could be provided on each conductive land 400 to enhance heat transfer.

FIG. 4C illustrates a subsequent step in the present process, in which a protective film 115 is formed over the carrier 410. This step is similar to that described above and shown in FIG. 1E′, and thus will not be further described here.

FIG. 4D illustrates a subsequent step in the present process, in which an underfill 140 is formed between the die 130, the conductive elements 120, the conductive lands 400 and the carrier 410. The underfill 140 may be formed by any of the processes described above, and may comprise any of the underfill materials described above. In an alternative embodiment shown in FIG. 4D′, the carrier 410 further includes at least one vent hole 119, which facilitates out-gassing and injection during mold injection.

FIG. 4E illustrates a subsequent step in the present process, in which the carrier 410 is released. Alternatively, the carrier may be released after forming the package body. Then, as shown in FIG. 4F, the substrate 132 of the die 130 is removed and a phosphor layer 150 is formed on the semiconductor layer 134. Removal of the substrate 132 and formation of the phosphor layer 150 may be performed using any of the processes described above with respect to FIG. 1G, and for any of the reasons described above.

FIG. 4G illustrates a subsequent step in the present process, in which a package body 160 is formed over the underfill 140 and the dies 130. The package body 160 encapsulates the die 130, the underfill 140, and the conductive elements 120, and the conductive lands 400 are embedded in the underfill 140, but exposed on their bottom surfaces 400b. The package body 160 may be formed with a lens portion 160a. The package body 160 may be made from any of the materials described above with respect to FIGS. 1H and 2, and according to any of the processes described above with respect to FIGS. 1H and 2.

In a subsequent step in the present process, the completed packages 40 illustrated in FIG. 4G are separated along the break lines A (FIG. 4F). For example, a singulation process may be performed to separate the packages 40 from one another. Once separated, the conductive lands 400 exposed on their bottom surfaces 400b can be connected to a mother board or a printed circuit board, for example.

FIG. 5 shows a schematic cross-sectional view of one embodiment of a package structure 50 made according to the foregoing manufacturing steps, except that the substrate 132 of the die 130 is retained and conversion substance particles 170, such as a phosphor, are added. The conversion substance particles 170 luminesce under certain conditions, providing a desired lighting appearance. Briefly, the package structure 50 includes at least one die 130 disposed on the conductive lands 400, with a plurality of conductive elements 120 and an underfill 140 disposed there between. Bottom surfaces 400b of the conductive lands 400 are flush with the underfill 140. A package body 160 encapsulates the die 130 and the underfill 140, and the conductive elements 120 and the conductive lands 400 are embedded in the underfill 140. The bottom surfaces 400b of the conductive lands 400 are exposed through the underfill 140 for further electrical connections. The die 130 is electrically connected to the conductive lands 400 through the conductive elements 120 and the pads 136. The pads 136 may function as cathodes, anodes or ground electrodes. The lens portion 160a may cover the entire package, or be any shape or size to suit design needs.

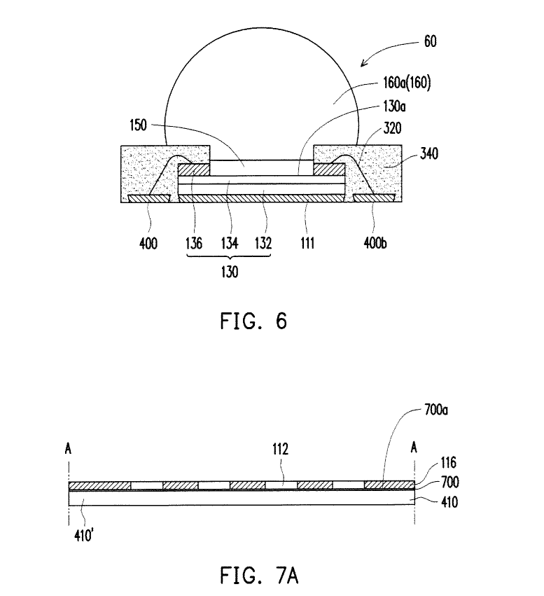

FIG. 6 shows a schematic cross-sectional view of another embodiment of the present semiconductor packages 60. In this embodiment, the die 130 is bonded to the conductive lands 400 via wire bonding. The die 130 is disposed directly on a die receiving pad 600 that is surrounded by the conductive lands 400. The die top surface 130a is a light emitting surface. The die 130 is electrically connected to the conductive lands 400 through the wires 320 and the pads 136. The molding compound 340 encapsulates the die receiving pad 600, the conductive lands 400, the wires 320 and the electrodes 136 of the die 130, but exposes the central part of the die 130 for illumination. A phosphor layer 150 is disposed on the semiconductor layer 134 between the electrodes 136. The package body 160 encapsulates the phosphor layer 150 and the molding compound 340. The conductive lands 400 are embedded in the molding compound 340, and the bottom surfaces 400b of the conductive lands 400 are exposed from the underfill for further electrical connections. The package body 160 may be any of the materials described above with respect to package bodies, and may further include conversion substance particles (not shown). The package body 160 may be formed with a lens portion 160a. The package body 160 may be formed completely on the phosphor layer 150 such that it does not cover any part of the top surface of the molding compound 340. Further, it may be desirable to form a package body in one molding operation, rather than forming the package body 160 and the molding compound 340 in two steps.

The embodiments of FIGS. 4-6 provide the same advantages discussed above with respect to the embodiments of FIGS. 1-3. Further, in the embodiments of FIGS. 4-6 the carrier 410 is released after the underfilling process. Thus, the total height or thickness of the molded package structure advantageously decreases. Compared with conventional process for ceramic based substrates, the cost of the package structure can be reduced because the transient carrier 410 may be recycled or reused.

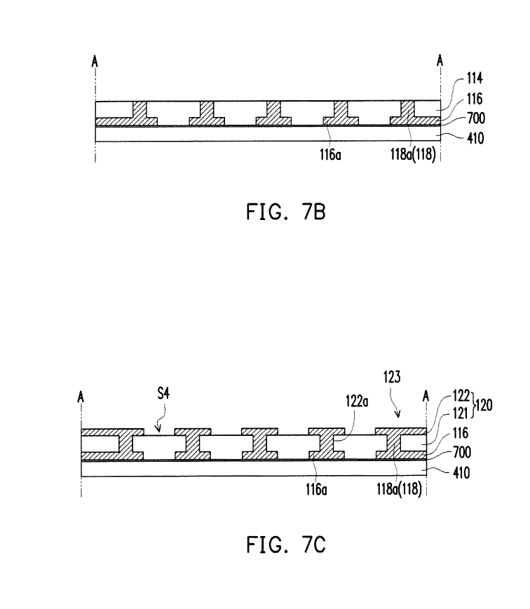

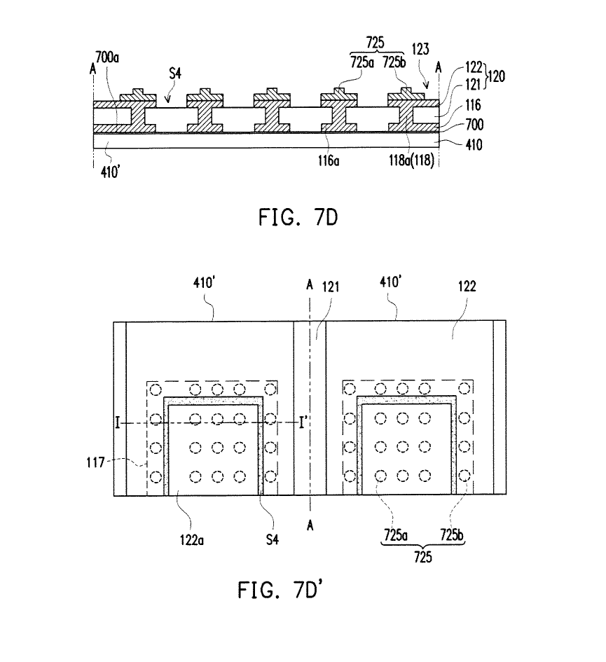

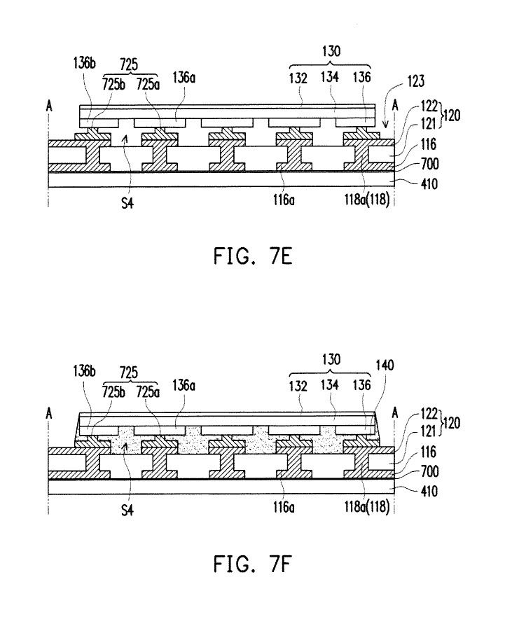

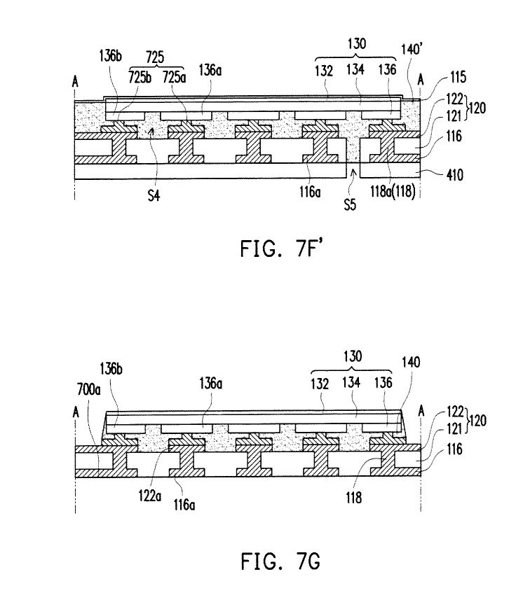

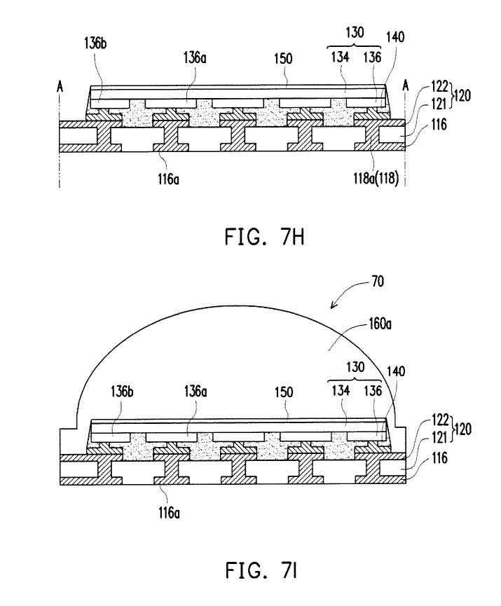

In FIGS. 7A-7I, an embodiment of a process for making a laminate or PCB (printed circuit board)-type semiconductor package structure is illustrated. Referring to FIG. 7A, the process begins with a carrier 410. The carrier 410 may, for example, function as a transient carrier for at least one package unit 70 (FIG. 7I), with the package units 70 arranged in strips or arrays. The illustrated carrier 410 includes a plurality of carrier units 410′, which are indicated by break lines A-A. In some embodiments a plurality of attached substrate units 110′ are fabricated simultaneously, or in sequence, and later separated from one another along the break lines A-A. For simplicity, the terms carrier 410 and carrier unit 410′ may be used interchangeably herein.

The carrier 410 may comprise any of the materials discussed above with respect to the carrier 410. The carrier 410 includes an upper layer 700. The upper substrate layer 700 may be a metal, such as copper, a copper alloy, or any other material. For example, the carrier 410 together with the upper substrate layer 700 can be parts of a copper clad laminate (CCL) structure or a stainless steel film coated with a copper foil.

A first photoresist layer 112 is formed on the upper surface 700a of the upper substrate layer 700. The first photoresist layer 112 can be formed by any of the processes described above with respect to FIG. 1A. Using the first photoresist layer 112 as a mask, a first conductive layer 116 is formed on the upper surface 700a that is not covered by the first photoresist layer 112. The first conductive layer 116 can be formed by any of the processes described above with respect to FIGS. 1A and 1B, and can have the same composition as the first conductive layer 116 described above.

Referring to the FIG. 7B, after removing the first photoresist layer 112, a second photoresist layer 114 is formed on the upper substrate layer 700 and covers a portion of the first conductive layer 116. Using the second photoresist layer 114 as a mask, a second conductive layer 118 is formed on the first conductive layer 116. Then, the second photoresist layer 114 is removed. The second conductive layer 118 can be formed by any of the processes described above with respect to FIGS. 1A and 1B, and can have the same composition as the second conductive layer 118 described above. The first conductive layer 116 includes a plurality of first wiring portions 116a. The second conductive layer 118 includes a plurality of metal pillars 118a respectively disposed on the first wiring portions 116a.

Referring to FIG. 7C, a double-layered sheet 120 including a dielectric layer 121 and a third conductive layer 122 is formed over the first and second conductive layers 116, 118. The dielectric layer 121 may be made of pre-impregnated materials (prepregs), such as BT (Bismaleimide Triazine), available from Mitsubishi Gas & Chemicals, or FR-4/FR-5 epoxy, available from Hitachi Chemicals or Doosan Chemicals, for example. The third conductive layer 122 may be made of materials similar to those of the first and second conductive layers 116, 118. The double-layered sheets 120 may be press-laminated to the conductive layers 116, 118, or formed by thermal compression, for example. Together, the conductive layers 116, 118, 122 and the dielectric layer 121 form a laminate structure 123. Optionally, ananti-tarnish layer (not shown), such as a nickel layer or a silver layer may be formed over the conductive layer 122 and covering the area outside the die shadow 117, to increase reflectivity.

The illustrated third conductive layer 122 includes a plurality of second wiring portions 122a. The second wiring portions 122a may be formed by etching a pattern in the laminated carrier 410 using a patterned photo resist (not shown). The wiring portions 122a are separated from one another by a gap S4. The wiring portions 122a, 123 can, for example, be laminated with patterns or patterned after press-lamination. The pattern of the third conductive layer 122 substantially corresponds to that of the first conductive layer 116 in FIG. 7C. However, the pattern of the third conductive layer 122 could be different from that of the first conductive layer 116 to suit design needs.

Referring to FIG. 7D, a plurality of conductive elements 725 is formed on the second wiring portions 122a of the third conductive layer 122. In the illustrated embodiment, the conductive elements 725 are studs, but could have any other structure, such as the structures discussed above with respect to the conductive elements 120. The conductive elements 725 also may be formed according to any method, including those described above with respect to the conductive elements 120, and could have any material composition, including those described above with respect to the conductive elements 120. In a subsequent step, a coating layer (not shown) is formed over the conductive elements 725 and the second wiring portions 122a. The coating layer may be formed by plating or any other process. The coating layer may be a stacked nickel/gold layer, for example, or any other material.

FIG. 7D′ provides a top plan view of the carrier 410. Note that FIG. 7D′ shows a different portion of the carrier 410 than FIG. 7D. Whereas FIG. 7D shows a portion of a single substrate unit 110′ taken along the cut line I-I′, FIG. 7D′ shows portions of two side-by-side substrate units 110′, with each substrate unit 110′ defined by the break line A. As shown in the top plan view of FIG. 7D′, the gap S4 surrounds central conductive elements 725a, with peripheral conductive elements 725b located outside the gap S4. The gap S4 also surrounds the second wiring portion 122a underlying the central conductive elements 725a. The locations of the openings S4 correspond to the die shadow locations 117. As illustrated, the size of the gap S4 is smaller than that of the die shadow 117, but it could be the same size as, or larger than, the die shadow 117. The gap S4 may have any shape, such as irregular, there may be several gaps S4 corresponding to each substrate unit to suit electrical design requirements. The locations of the conductive elements 725 correspond to the locations of electrodes on the die 130, and the locations of the conductive elements 725 are within the die shadow 117. The number and locations of the conductive elements 725 can be modified to suit design needs, such as desired thermal characteristic. For example, there may be several conductive elements 725 per die electrode.

Although the conductive elements 725 in FIGS. 7D and 7D′ are formed on the laminate structure 123, they could be provided on the dies 130 before mounting the dies 130 to the laminate substrate structure, depending on the product design or depending on cost considerations. Taking copper pillars as an example, it is preferable to provide the pillars on the dies 130 before mounting, as better pillar planarity can be achieved. Furthermore, it is possible to connect the dies 130 to the laminate substrate structure by wire bonding.

Referring to FIG. 7E, a plurality of dies 130 is mounted over the laminate structure 123, although only one die 130 is shown. The dies 130 are coupled to the conductive elements 725 through any suitable process. For example, the dies 130 may be disposed on the conductive elements 725 and then connected through thermo-sonic bonding. The die 130 may be an LED chip, which is described in detail above. The die 130 is electrically connected to the first and third conductive layers 116, 122 through the conductive elements 725 and the pads 136. The pads 136 may function as cathodes, anodes or ground electrodes. For example, the die 130, being an LED power chip, the central electrodes 136a surrounded by the opening S4 may be anodes, while the peripheral electrodes 136b outside the opening S4 may be cathodes, or vice versa. The locations of the conductive elements 725 may correspond to the locations of the electrodes of the die 130 in a one-to-one fashion, or a plural-to-one fashion to increase thermal and electrical conductivity. The central pads 136a are connected with the central conductive elements 725a, while the peripheral pads 136b are connected with the peripheral conductive elements 725b. For example, the central electrodes surrounded by the opening S4 can be electrically isolated from the peripheral electrodes outside the opening S4.

Referring to FIG. 7F, an underfill 140 is formed between the die 130 and the coating layer 126 and fills between the conductive elements 725 and the electrodes 136 under the die 130. The underfill 140 may be formed by any underfill process described above, or any other process. Further, the underfill 140 may comprise any underfill material described above, or any other material. The underfill 140 advantageously reinforces joints of the package, thereby increasing the package's strength.

Referring to FIG. 7F′, the underfill 140′ may be formed by a flushed under molding process or a molded underfill process. Using a compliant film 115 attached to the inner surface of the transfer mold (not shown) in the film assisted molding process over the dies 130, the underfill material flushes over the carrier 410 and fills between the dies 130 and the conductive elements 725 and between the compliant film 115 and the conductive layer 122. Preferably, the compliant film 115 is in the form of a continuously fed tape, and the transfer mold is placed over a portion of the film tape during the underfill filling process. Additionally, at least one vent hole S5 may optionally be formed in the laminate structure 123 and the carrier 410. The vent hole S5 facilitates out-gassing during mold injection. Alternatively, the vent hole S5 may be used in a vacuum assisted mold process to form the underfill 140′.

Referring to FIG. 7G, the carrier 410 is released. The upper substrate layer 700 may be removed along with the carrier 410. If necessary, a flash etching process, or another process, may be performed to completely remove the upper substrate layer 700. Optionally, a bottom coating layer (not shown) may be formed on the exposed surface of the first conductive layer 116 after the carrier is released. Alternatively, the carrier 410 and the upper substrate layer 700 may be released after the package body has been molded in a subsequent step. Herein, the first and second conductive layers 116, 118 and the double-layered sheet 120 may be regarded as a laminate substrate having the portions 122a as a top conductive pattern and the conductive portions 116a as a bottom conductive pattern.

Referring to FIG. 7H, the substrate 132 of the die 130 is removed and a phosphor layer 150 is formed on the semiconductor layer 134. Removal of the substrate 132 and formation of the phosphor layer 150 may be performed using any of the processes described above with respect to FIG. 1G, and for any of the reasons described above.

Referring to FIG. 7I, a package body 160 is formed over the coating layer 126 to encapsulate the die 130, the conductive elements 725 and the underfill 140. The package body 160 may be formed with a lens portion 160a. The package body 160 may be made from any of the materials described above with respect to FIGS. 1H and 2, and according to any of the processes described above with respect to FIGS. 1H and 2.

In a subsequent step in the present process, the completed packages 70 illustrated in FIG. 7I are separated along the break lines A (FIG. 7H). For example, a singulation process may be performed to separate the packages 70 from one another.

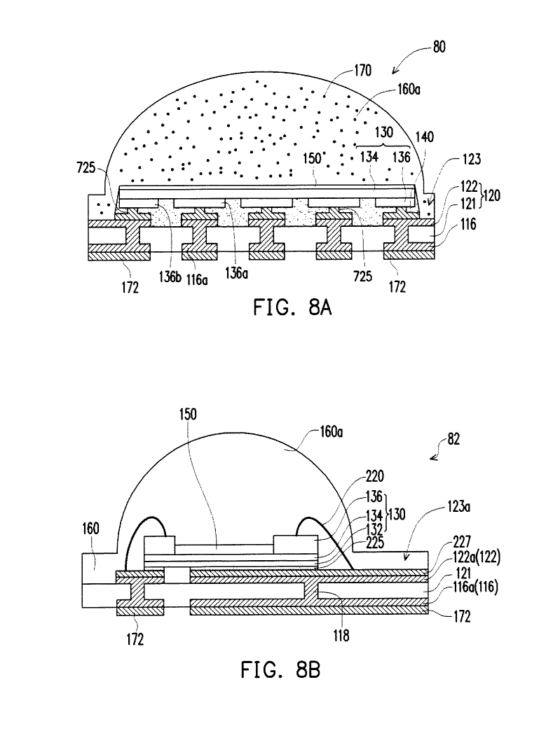

FIG. 8A shows a schematic cross-sectional view of one embodiment of a package structure 80 assembled according to the method of FIGS. 7A-7I. The package structure 80 includes at least one die 130 disposed over the laminate substrate 123, a plurality of conductive elements 725 between the die 130 and the wiring portions 122a, and an underfill 140 there between. The package body 160 encapsulates the die 130, the underfill 140, the conductive elements 725 and the wiring portions 122a.

The die 130 is electrically connected to the wiring portions 116a, 122a through the conductive elements 725 and the pads 136. The conductive elements 725 and the underlying wiring portions 116a, 122a can facilitate heat dissipation of the package unit. The package body 160 further includes conversion substance particles 170, which are described above. In addition, a bottom coating layer 172 is located on the first conductive layer 116. The bottom coating layer 172 enhances electrical conductivity, and may be a nickel/gold layer, or any other material composition.

FIG. 8B shows a schematic cross-sectional view of another embodiment of the present package structures 82. The package structure 82 includes at least one die 130 disposed on a conductive coating layer 227 of the laminate substrate 123a. A plurality of wires 220 electrically couples the die 130 to the coating layer 227 via the pads 136. A package body 160 encapsulates the die 130, the wires 220, and the laminate substrate 123a. The coating layer 227 may be formed by pattern plating, or by any other process. The coating layer 227 enhances electrical conductivity, and may be a stacked nickel/gold layer, or any other material composition. Also, an adhesive layer 225 between the die 130 and the coating layer 227 secures the attachment between the die 130 and the laminate substrate 123a.

The die 130 is similar to those described above, but includes a phosphor layer 150 coated on the semiconductor layer 134 without covering the electrodes 136. The pads 136 may function as cathodes, anodes or ground electrodes. The package body 160 may be made of any of the package body materials discussed above, or any other material. The package structure 82 also includes the bottom coating layer 172, which is discussed above with respect to FIG. 8A. While only one wire 220 is shown extending from each electrode 136 in FIG. 8B, multiple wires 220 may be used to interconnect a given electrode 136 for improved electrical and thermal performance to accommodate high current devices.

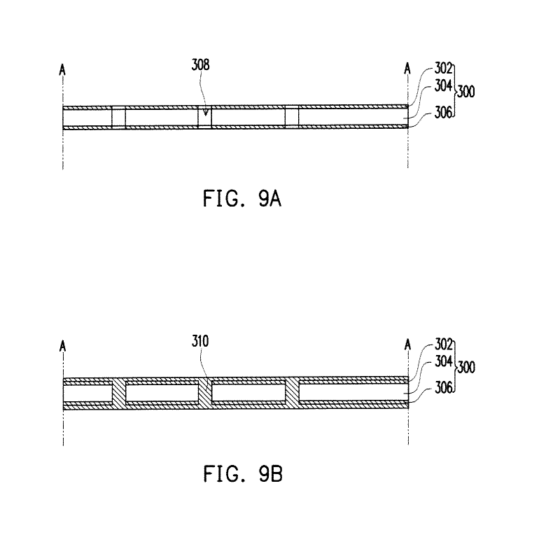

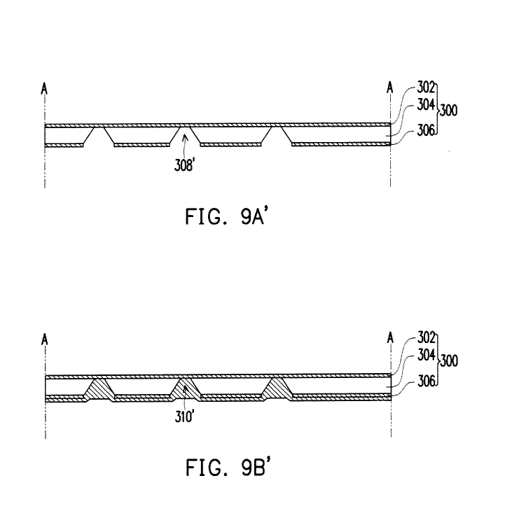

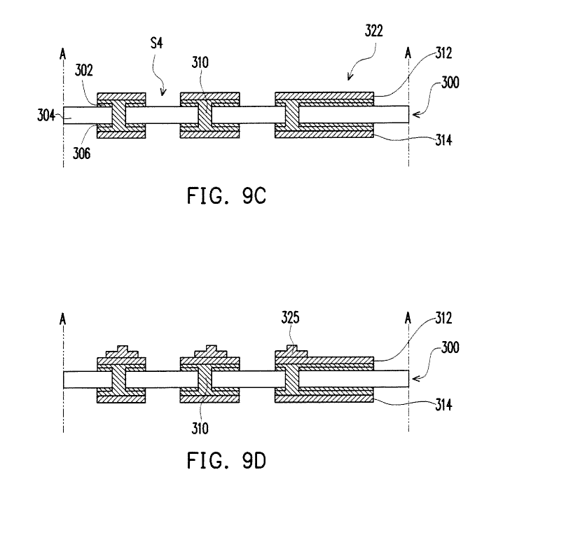

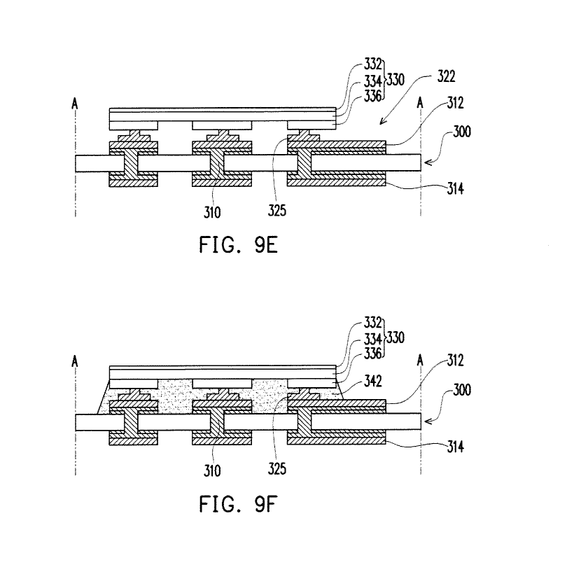

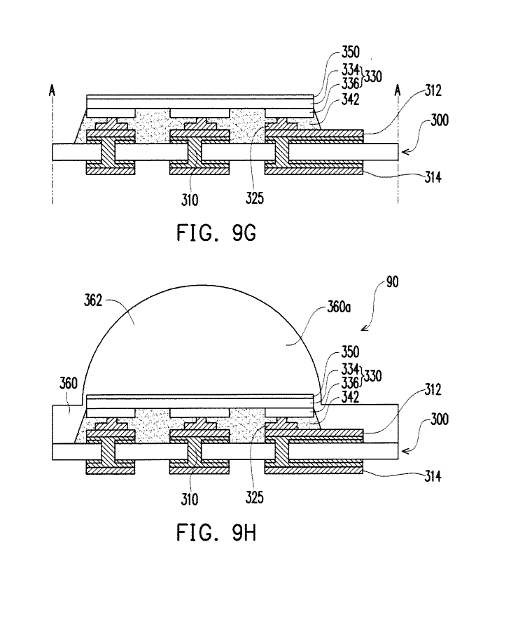

In FIGS. 9A-9H, another embodiment of a process for making laminate or PCB (printed circuit board)-type semiconductor package structure is illustrated. Referring to FIG. 9A, the process begins with a double-sided lamination structure 300. As in previous embodiments, the illustrated structure 300 is one of a plurality of structures 300, which are contiguous with one another and subdivided by the break lines A-A.

The structure 300 includes a first conductive layer 302, a second conductive layer 306, and a core structure 304 sandwiched in between. The material of the first and the second conductive layers 302, 306 may be similar to that of the conductive layers described above, or any other material. The first and the second conductive layers 302, 306 may be formed by any process described above with respect to conductive layers, or by any other process. The core structure 304 may be a preformed prepreg comprising resin and glass fiber, or any other material. The double-sided lamination structure 300 may be a copper clad laminate (CCL) made of Ajinomoto Build-up Film (ABF), Bismaleimide-Triazine (BT) or FR-4/FR-5 epoxies, for example. Through holes 308 are formed in the structure 300 by any desired process, such as mechanical drilling or laser drilling.

Referring to FIG. 9B, a plating process, such as electroplating, plates the through holes 308 to form plated vias 310. The through holes may be plated such that the holes 308 are completely filled as shown, or plated such that only sidewalls of the holes 308 are covered with plating material. The plating process may also increase a thickness of each of the first and the second conductive layers 302, 306, as shown in FIG. 9B.

In an alternative embodiment, as shown in FIGS. 9A′ and 9B′, instead of forming through holes 308, a plurality of blind vias 308′ (FIG. 9A′) may be formed and then electroplated to form plated plugs 310′ (FIG. 9B′). Blind vias are typically made in thinner CCLs, and may be made by laser drilling. They allow for ultrathin substrates. In either embodiment, interconnection structures, such as plated vias 310 or plugs 310′, electrically connect the first and second conductive layers 302, 306.

FIG. 9C illustrates a subsequent step in the present process, following FIG. 9B. A first conductive pattern 312 and a second conductive pattern 314 are respectively formed on the top and bottom surfaces of the laminate structure 300. The conductive patterns 312, 314 may enhance electrical conductivity, and may be made of gold, or any other material. Using the first and second conductive patterns 312, 314 as etching masks, the underlying first and second conductive layers 302, 306 are etched until the core structure 304 is exposed and a plurality of openings S4 is formed. At this stage, the laminate substrate structure 322 is defined.

Referring to FIG. 9D, a plurality of conductive elements 325 is formed on the first conductive pattern 312. The conductive elements 325 may be formed by any of the processes described above with respect to conductive elements, or any other process. The conductive elements 325 may have any material composition described above with respect to conductive elements, or any other material composition. The illustrated conductive elements 325 are studs, but could be any of the structural configurations described above with respect to conductive elements. Although the conductive elements 325 are shown as being formed on the laminate substrate 322, they may alternatively be provided on the dies 130 before mounting the dies 130 to the laminate substrate 322.

Referring to FIG. 9E, a plurality of dies 130 is mounted over the laminate substrate 322 and disposed on the conductive elements 325. The die 130 may be coupled to the conductive elements 325 through any of the methods described above with respect to dies. The die 130 is electrically connected to the first conductive pattern 312 through the conductive elements 325 and the pads 336. The characteristics of the die 130 and its interconnections are similar to that described above with respect to dies.

Referring to FIG. 9F, an underfill 342 is formed between the die 130 and the first conductive pattern 312, and fills the space between the conductive elements 325 and the electrodes 336 on the die 130. The underfill 342 may be formed by through any of the methods described above with respect to underfills, or any other method. The underfill 342 may comprise any of the material compositions described above with respect to underfills, or any other material composition. The underfill 342 advantageously reinforces the strength of the package's joints in the area of the underfill 342, thereby reinforcing the package's strength and durability.

Referring to FIG. 9G, the substrate 332 of the die 130 is removed by any of the processes described above with respect to the substrate 332. Subsequently, a phosphor layer 350 is formed on the semiconductor layer 334. Referring to FIG. 9H, a package body 360 is formed over the laminate structure 300 to encapsulate the die 130, the conductive elements 325, the first conductive pattern 312 and the underfill 342. The package body 360 may be formed with a lens portion 360a. The package body 360 may comprise any of the package body materials described above, or any other material. The domed portion 362 of the package body 360 may extend over the entire laminate structure, or take on different shapes to suit product design needs.

In a subsequent step in the present process, the completed packages 90 illustrated in FIG. 9H are separated along the break lines A (FIG. 9G). For example, a singulation process may be performed to separate the packages 90 from one another.

The embodiments of FIGS. 7-9 provide the same advantages discussed above with respect to the embodiments of FIGS. 1-6. The molded underfill with injection/vent holes are optional and not shown here. These laminate LED packages are particularly easy to expand into LED systems by adding additional circuits for controller, RF, sensor, power management, etc. The two layer laminate substrates enable the increased wireability needed to interconnect those functions with the LED function while thermally separating the two areas.

While the invention has been described with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor package, comprising:
a leadframe including an isolated block and at least one lead at a periphery of the package, the isolated block having a lateral surface, the lateral surface having a sloped upper portion and a sloped lower portion, wherein a junction of the sloped upper portion and the sloped lower portion defines an apex, the at least one lead having a lateral surface, the lateral surface having a sloped upper portion and a sloped lower portion, wherein a junction of the sloped upper portion and the sloped lower portion defines an apex;
a plurality of conductive standoffs coupled to an upper surface of the isolated block and the at least one lead;
a die coupled to the plurality of conductive standoffs with a space between the die and the isolated block; and
a package body at least partially encapsulating the die, the sloped upper portions of the isolated block, and the at least one lead, wherein the sloped lower portions of the isolated block and the at least one lead protrude from the package body.

2. The semiconductor package of claim 1, wherein the leadframe includes an opening surrounding the isolated block, the opening electrically isolating the isolated block from the balance of the substrate.

3. The semiconductor package of claim 1, wherein the package body contains thermally conductive particles.

4. The semiconductor package of claim 1, wherein the die is a light-emitting diode (LED) die.

5. The semiconductor package of claim 4, wherein the package body includes a lens portion over the die.

6. The semiconductor package of claim 1, wherein the leadframe is copper or a copper alloy, and upper and lower surfaces thereof comprise a nickel/gold layer.

7. The semiconductor package of claim 1, wherein the conductive standoffs are pillars.

8. A semiconductor package, comprising:
a leadframe including an isolated block and at least one lead at a periphery of the package, the isolated block having a lateral surface, the lateral surface having a sloped upper portion and a sloped lower portion, wherein a junction of the sloped upper portion and the sloped lower portion defines an apex, the at least one lead having a lateral surface, the lateral surface having a sloped upper portion and a sloped lower portion, wherein a junction of the sloped upper portion and the sloped lower portion defines an apex;
a die coupled to the isolated block and electrically connected to the at least one lead;
a first encapsulant encapsulating a portion of the die, the sloped upper surfaces of the isolated block, and the at least one lead, the sloped lower portions of the isolated block and the at least one lead protruding from the first encapsulant; and
a second encapsulant encapsulating a light emitting portion of the die, wherein the second encapsulant permits the passage of light.

9. The semiconductor package of claim 8, wherein the leadframe includes an opening defining an isolated block, the opening electrically isolating the isolated block from the balance of the substrate.

10. The semiconductor package of claim 8, wherein the first encapsulant contains thermally conductive particles.

11. The semiconductor package of claim 8, wherein the die is a light-emitting diode (LED) die.

12. The semiconductor package of claim 11, wherein the second encapsulant includes a lens portion over the die.

13. The semiconductor package of claim 8, wherein the leadframe is copper or a copper alloy, and upper and lower surfaces thereof comprise a nickel/gold layer.

14. The semiconductor package of claim 8, wherein the conductive standoffs are pillars.

15. A method of making a semiconductor package, the method comprising:
forming conductive layers on top and bottom surfaces of a substrate;
forming an opening in the substrate to thereby define an isolated block and a plurality of leads at a periphery of the package, the isolated block having a lateral surface with a sloped upper portion and a sloped lower portion, wherein a junction of the sloped upper portion and the sloped lower portion defines an apex, each of the leads having a lateral surface, the lateral surface having a sloped upper portion and a sloped lower portion, wherein a junction of the sloped upper portion and the sloped lower portion defines an apex;
forming a plurality of conductive standoffs on an upper surface of the isolated block and the leads;
coupling a die to the plurality of conductive standoffs with a space between the die and the isolated block; and
forming a package body coupled to the package such that the body at least partially encapsulates the die, the sloped upper portions of the isolated block, and the sloped upper portions of the leads, wherein the sloped lower portions of the isolated block and the leads protrude from the package body.

16. The method of claim 15, wherein forming the opening electrically isolates the isolated block from the balance of the substrate.

17. The method of claim 15, wherein the package body contains thermally conductive particles.

18. The method of claim 15, wherein the die is a light-emitting diode (LED) die.

19. The method of claim 18, further comprising forming a lens portion in the package body over the die.

20. The method of claim 15, wherein forming the conductive standoffs comprises forming pillars.
